(19) United States
(12) Patent Application Publication
(10) Pub. No.: US 2007/0013068 A1
(43) Pub. Date: Jan. 18, 2007

(54) Integrated circuit package and method with an electrical component embedded in a substrate via

(75) Inventors: Yogendra Ranade, Fremont, CA (US); Parthasarathy Rajagopalan, Milpitas, CA (US); Jeff Hall, San Jose, CA (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/156,151

(22) Filed: Jun. 17, 2005

(51) Int. Cl. H01L 23/48

(52) U.S. Cl. 257/738

(57) ABSTRACT

An integrated circuit package and method exploit the volume enclosed by the package substrate vias. In one embodiment, an integrated circuit package includes a first substrate having electrically conductive layers formed on substantially parallel surfaces of the first substrate, a second substrate having electrically conductive layers formed on substantially parallel surfaces of the second substrate, a substrate via formed through the first substrate and the second substrate to form an electrical connection between at least two electrically conductive layers of the first substrate and between at least two electrically conductive layers of the second substrate, an electrical component having a first end and a second end inserted into the substrate via so that the first end extends at least partially inside the first substrate and the second end extends at least partially inside the second substrate, and an electrically insulating layer formed between the first substrate and the second substrate.

### BACKGROUND OF THE INVENTION

1. Field of the Invention

The present invention is directed to the design and manufacture of integrated circuits. More specifically, but without limitation thereto, the present invention is directed to methods of constructing an integrated circuit package.

2. Description of Related Art

One function of an integrated circuit package is to provide interconnections between an integrated circuit die and pins that extend from the package to connect with a circuit board. Integrated circuit packages typically include decoupling capacitors for simultaneous switching output (SSO) noise reduction. Previously, these decoupling capacitors have been placed on the surface or in the internal layers of the integrated circuit package substrate.

### SUMMARY OF THE INVENTION

An integrated circuit package and method exploit the volume enclosed by the package substrate vias to place electrical components. In one embodiment, an integrated circuit package includes a first substrate having electrically conductive layers formed on substantially parallel surfaces of the first substrate, a second substrate having electrically conductive layers formed on substantially parallel surfaces of the second substrate, a substrate via formed through the first substrate and the second substrate to form an electrical connection between at least two electrically conductive layers of the first substrate and between at least two electrically conductive layers of the second substrate, an electrical component having a first end and a second end inserted in the substrate via so that the first end extends at least partially inside the first substrate and the second end extends at least partially inside the second substrate, and an electrically insulating layer formed between the first substrate and the second substrate.

In another embodiment, a method includes steps of:
providing a first substrate having electrically conductive layers formed on substantially parallel surfaces of the first substrate;
providing a second substrate having electrically conductive layers formed on substantially parallel surfaces of the second substrate;
forming a substrate via through the first substrate and the second substrate to form an electrical connection between at least two electrically conductive layers of the first substrate and between at least two electrically conductive layers of the second substrate;
providing an electrical component having a first end and a second end;
inserting the electrical component in the substrate via so that the first end extends at least partially inside the first substrate and the second end extends at least partially inside the second substrate; and
forming an electrically insulating layer between the first substrate and the second substrate.

In further embodiments, an electrical connection is formed between the first end of the electrical component and the at least two electrically conductive layers of the first substrate and an electrical connection is formed between the second end of the electrical component and the at least two electrically conductive layers of the second substrate.

In various other embodiments, the electrical component is a resistor, a capacitor, or other passive element.

### BRIEF DESCRIPTION OF THE DRAWINGS

The above and other aspects, features and advantages will become more apparent from the description in conjunction with the following drawings presented by way of example and not limitation, wherein like references indicate similar elements throughout the several views of the drawings, and wherein:

FIG. 1 illustrates a side view of an integrated circuit package of the prior art;

FIG. 2 illustrates a magnified section of the package substrate of FIG. 1;

FIG. 3 illustrates a magnified section of an embodiment of an integrated circuit package with a substrate via formed through a first and a second substrate;

FIG. 4 illustrates a magnified section of FIG. 3 with an electrical component inserted in the substrate via;

FIG. 5 illustrates a magnified section of FIG. 4 with an additional electrically insulating layer formed between the first substrate and the second substrate;

FIG. 6 illustrates a side view of the composite substrate of FIG. 5 with an electrically conductive coupling formed between one end of the electrical component and an electrically conductive layer of the first substrate;

FIG. 7 illustrates a side view of the composite substrate of FIG. 6 with an electrically conductive coupling formed between the other end of the electrical component and an electrically conductive layer of the second substrate; and

FIG. 8 illustrates a flow chart of a method according to an embodiment of an integrated circuit package substrate with an electrical component embedded in a substrate via.

Elements in the figures are illustrated for simplicity and clarity and have not necessarily been drawn to scale. For example, the dimensions, sizing, and/or relative placement of some of the elements in the figures may be exaggerated relative to other elements to clarify distinctive features of the illustrated embodiments. Also, common but well-understood elements that are useful or necessary in a commercially feasible embodiment are often not depicted in order to facilitate a less obstructed view of the illustrated embodiments.

### DESCRIPTION OF THE ILLUSTRATED EMBODIMENTS

The following description is not to be taken in a limiting sense, rather for the purpose of describing by specific examples the general principles that are incorporated into the illustrated embodiments. For example, certain actions or steps may be described or depicted in a specific order to be performed. However, practitioners of the art will understand that the specific order is only given by way of example and that the specific order does not exclude performing the described steps in another order to achieve substantially the same result. Also, the terms and expressions used in the description have the ordinary meanings accorded to such terms and expressions in the corresponding respective areas of inquiry and study except where other meanings have been specifically set forth herein.

A disadvantage of placing decoupling capacitors on the surface or in the internal layers of the integrated circuit package substrate is that the area of the integrated circuit package is typically increased in proportion to the number of added decoupling capacitors. An integrated circuit package is described below that overcomes this disadvantage by exploiting the volume enclosed within the substrate vias of the integrated circuit package to place capacitors as well as other electrical components.

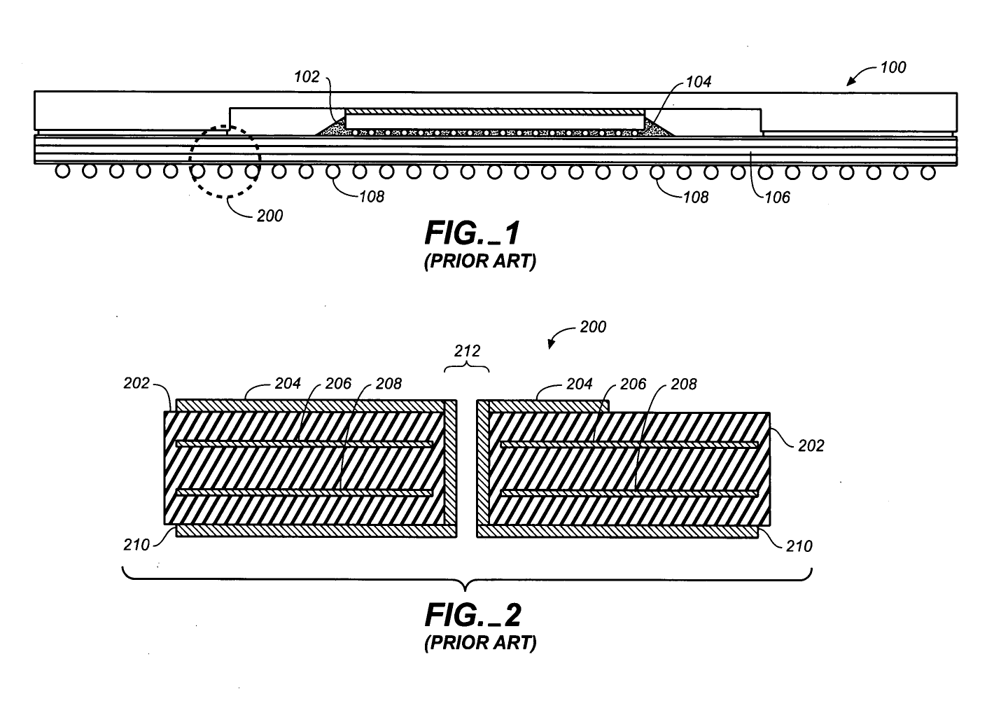

FIG. 1 illustrates a side view 100 of an integrated circuit package of the prior art. Shown in FIG. 1 are an integrated circuit die 102, solder bumps 104, a package substrate 106, and package pins 108.

In FIG. 1, the solder bumps 104 provide an electrical connection between the integrated circuit die 102 and the package substrate 106. The package substrate 106 provides an electrical connection between the solder bumps 104 and the package pins 108.

FIG. 2 illustrates a magnified section 200 of the package substrate of FIG. 1. Shown in FIG. 2 are an electrically non-conductive layer 202, electrically conductive layers 204, 206, 208, and 210, and a substrate via 212.

In FIG. 2, the electrically conductive layers 204, 206, 208, and 210 route signals from the integrated circuit die 102 in FIG. 1 to the package pins 108. Typically, the electrically conductive layers 204, 206, 208, and 210 are formed on substantially parallel surfaces of the electrically non-conductive layer 202, and wire traces are formed in the electrically conductive layers 204, 206, 208, and 210 to route signals between the integrated circuit die 102 and the package pins 108. The substrate via 212 is formed through the electrically non-conductive layer 202 and plated with an electrically conductive material such as copper to provide an electrical connection between the electrically conductive layers 204 and 210.

The integrated circuit package and method described below exploit the volume enclosed by the package substrate vias to place capacitors and other electrical components such as resistors and other passive electrical components. In one embodiment, an integrated circuit package includes:
a first substrate having electrically conductive layers formed on substantially parallel surfaces of the first substrate;
a second substrate having electrically conductive layers formed on substantially parallel surfaces of the second substrate;
a substrate via formed through the first substrate and the second substrate to form an electrical connection between at least two electrically conductive layers of the first substrate and between at least two electrically conductive layers of the second substrate;
an electrical component having a first end and a second end inserted in the substrate via so that the first end extends at least partially inside the first substrate and the second end extends at least partially inside the second substrate; and
an electrically insulating layer formed between the first substrate and the second substrate.

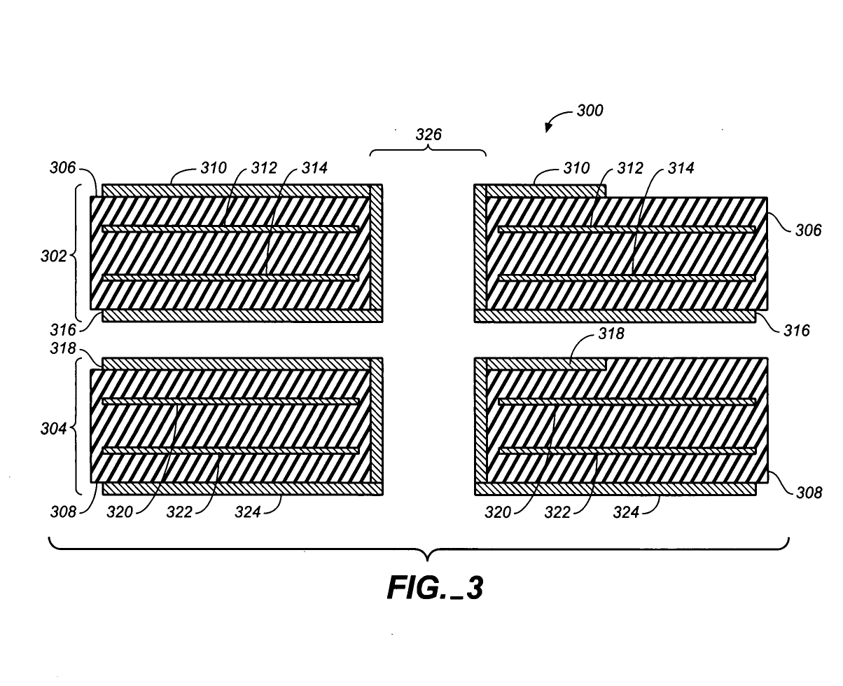

FIG. 3 illustrates a magnified section 300 of an embodiment of an integrated circuit package with a substrate via formed through a first and second substrate. Shown in FIG. 3 are a first substrate 302, a second substrate 304, electrically insulating layers 306 and 308, electrically conductive layers 310, 312, 314, and 316 of the first substrate 302, electrically conductive layers 318, 320, 322, and 324 of the second substrate 304, and a substrate via 326.

In FIG. 3, the first substrate 302, the second substrate 304, and the substrate via 326 are each formed, for example, in the same manner as the single package substrate 106 in FIG. 1. The substrate via 326 provides an electrical connection between the electrically conductive layers 310 and 316 and between the electrically conductive layers 318 and 324.

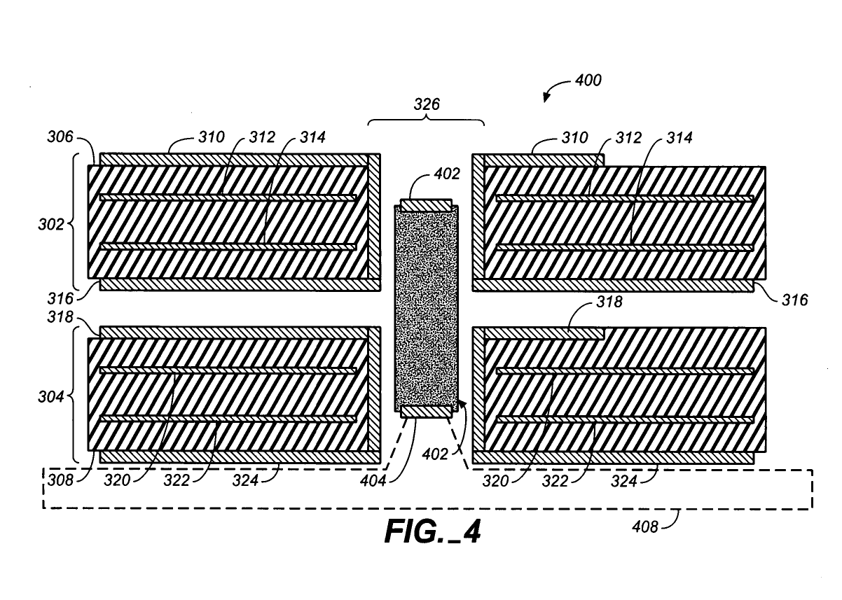

FIG. 4 illustrates a magnified section 400 of FIG. 3 with an electrical component inserted in the substrate via. Shown in FIG. 4 are a first substrate 302, a second substrate 304, electrically insulating layers 306 and 308, electrically insulating layers 306 and 308, electrically conductive layers 310, 312, 314, and 316 of the first substrate 302, electrically conductive layers 318, 320, 322, and 324 of the second substrate 304, a substrate via 326, an electrical component 402, opposite ends 404 and 406, and a backing plate 408.

In FIG. 4, the electrical component 402 may be, for example, a capacitor, a resistor, or other passive electrical component having a diameter appropriately dimensioned to fit inside the substrate via 326. The length of the electrical component 402 may be selected so that the opposite ends 404 and 406 are flush with the outside surfaces of the first substrate 302 and the second substrate 304. Alternatively, the length of the electrical component 402 may be selected so that the opposite ends 404 and 406 extend only partially into the substrate via 326 through the first substrate 302 and the second substrate 304. The opposite ends 404 and 406 of the electrical component 402 are made electrically conductive according to well known techniques for making electrical connections between the electrical component 402 and the electrically conductive layers 310 and 324. The electrical component 402 is inserted into the substrate via 326 so that one end extends at least partially through the first substrate 302 and the other end extends at least partially through the second substrate 304. The electrical component 402 is temporarily held in place, for example, by the backing plate 408 placed against the bottom of the second substrate 304. Other methods may be used to hold the electrical component 402 temporarily in place inside the substrate via 326 according to well-known techniques.

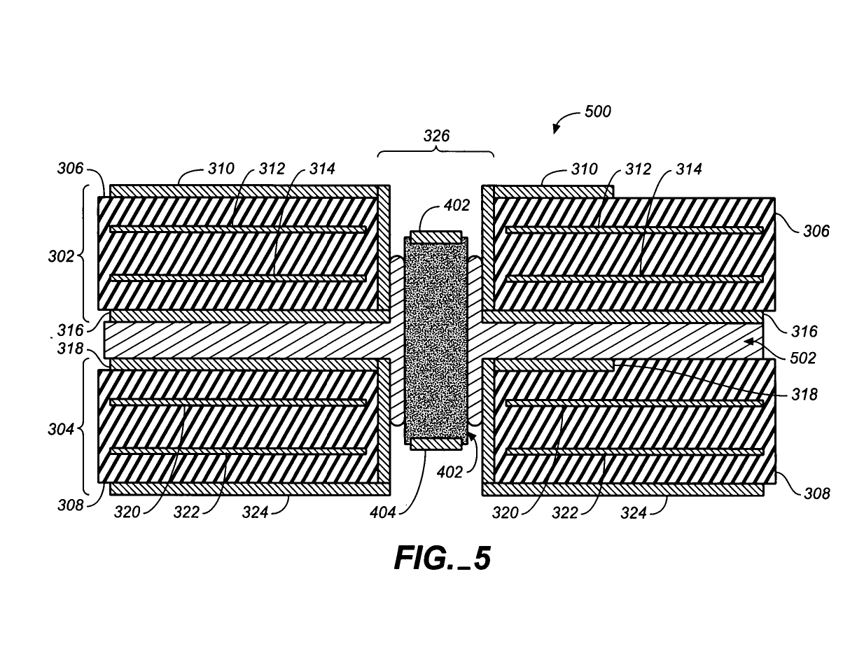

FIG. 5 illustrates a magnified section 500 of FIG. 4 with an additional electrically insulating layer formed between the first substrate and the second substrate. Shown in FIG. 5 are a first substrate 302, a second substrate 304, electrically insulating layers 306 and 308, electrically insulating layers 306 and 308, electrically conductive layers 310, 312, 314, and 316 of the first substrate 302, electrically conductive layers 318, 320, 322, and 324 of the second substrate 304, a substrate via 326, an electrical component 402, opposite ends 404 and 406 and an additional electrically insulating layer 502.

In FIG. 5, the additional electrically insulating layer 502 provides electrical isolation between the first substrate 302 and the second substrate 304 and permanently secures the electrical component 402 inside the substrate via 326. The electrically insulating layer 502 may be formed, for example, by injecting an electrically non-conductive liquid such as a liquid filler between the first substrate 302 and the second substrate 304 and curing the liquid into a solid. The electrically insulating layer 502 secures the first substrate 302 to the second substrate 304 and secures the electrical component 402 inside the substrate via 326 to form a composite substrate.

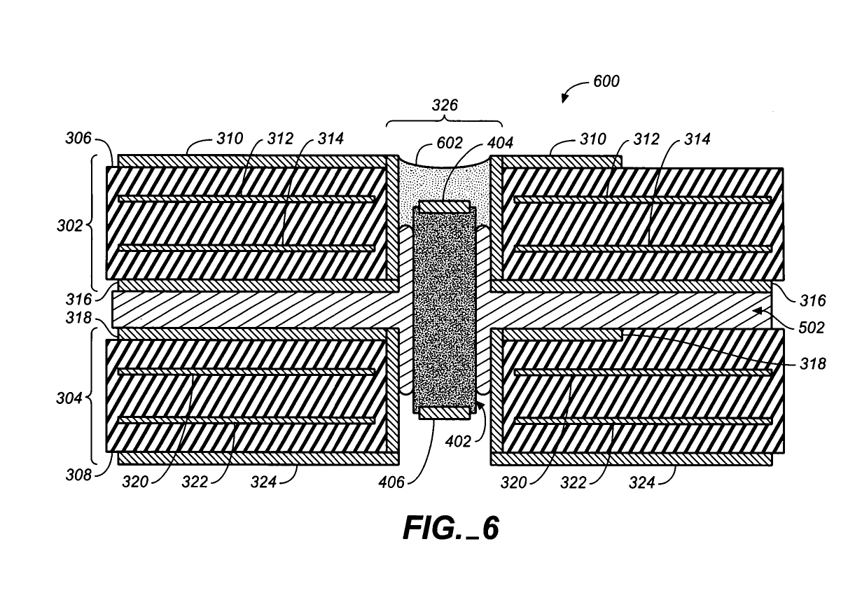

FIG. 6 illustrates a side view 600 of the composite substrate of FIG. 5 with an electrically conductive coupling formed between one end of the electrical component and an electrically conductive layer of the first substrate. Shown in FIG. 6 are a first substrate 302, a second substrate 304, electrically insulating layers 306 and 308, electrically conductive layers 310, 312, 314, and 316 of the first substrate 302, electrically conductive layers 318, 320, 322, and 324 of the second substrate 304, a substrate via 326, an electrical component 402, opposite ends 404 and 406, an additional electrically insulating layer 502, and an electrically conductive coupling 602.

In FIG. 6, the electrically conductive coupling 602 provides an electrical connection between one end of the electrical component 402 and the electrically conductive layer 310 of the first substrate 302. The electrically conductive coupling 602 may be made, for example, by injecting an electrically conductive liquid such as a conductive epoxy compound into the end of the substrate via 326 on top of the first substrate 302 and curing the liquid into a solid.

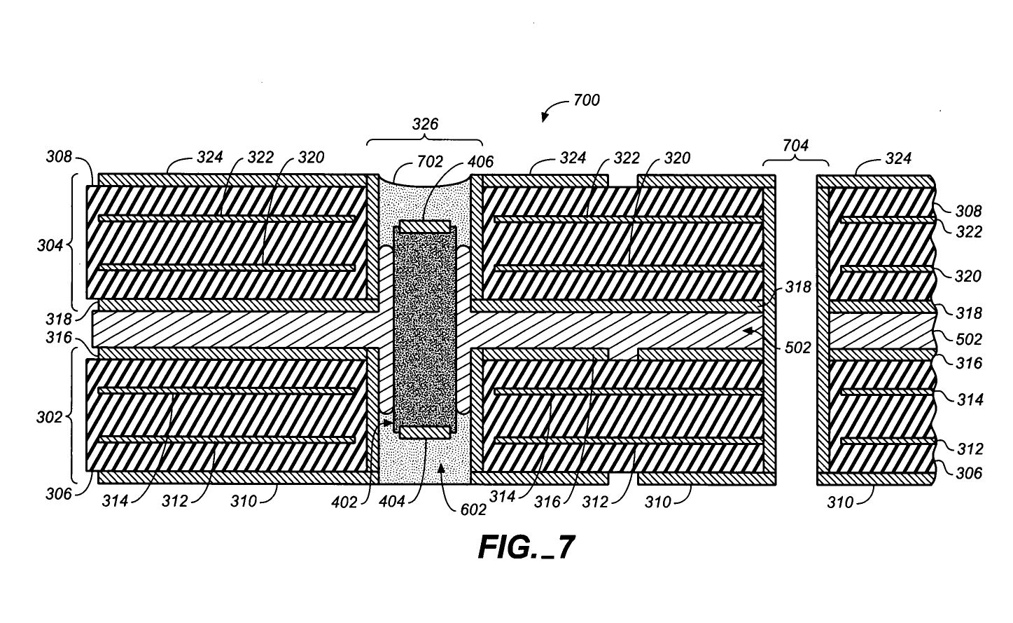

FIG. 7 illustrates a side view 700 of the composite substrate of FIG. 6 with an electrically conductive coupling formed between the other end of the electrical component and an electrically conductive layer of the second substrate. Shown in FIG. 7 are a first substrate 302, a second substrate 304, electrically insulating layers 306 and 308, electrically conductive layers 310, 312, 314, and 316 of the first substrate 302, electrically conductive layers 318, 320, 322, and 324 of the second substrate 304, a substrate via 326, an electrical component 402, opposite ends 404 and 406, an additional electrically insulating layer 502, electrically conductive couplings 602 and 702, and a conventional substrate via 704.

In FIG. 7, the electrically conductive coupling 702 provides an electrical connection between the other end of the electrical component 402 and the electrically conductive layer 324 of the second substrate 304. The electrically conductive coupling 702 may be made in the same manner described above for the electrically conductive coupling 602. The composite substrate may be inverted as shown in FIG. 7 to facilitate injecting an electrically conductive liquid into the end of the substrate via 326 on the top of the second substrate 304.

In addition to the substrate via 326 that provides electrical connections and vertical placement space for the electrical component 402, conventional substrate vias such as the conventional substrate via 704 may optionally be formed in the composite substrate according to well known techniques through the first substrate 302 and the second substrate 304 and plated through the electrically insulating layer 502 to provide an electrical connection between wire traces in the electrically conductive layer 310 and wire traces in the electrically conductive layer 324. The optional conventional vias are preferably formed between wire traces that are not bridged by the electrical components embedded in the substrate vias to avoid short-circuiting the embedded components.

In another embodiment, a method includes steps of:
providing a first substrate having electrically conductive layers formed on substantially parallel surfaces of the first substrate;
providing a second substrate having electrically conductive layers formed on substantially parallel surfaces of the second substrate;
forming a substrate via through the first substrate and the second substrate to form an electrical connection between at least two electrically conductive layers of the first substrate and between at least two electrically conductive layers of the second substrate;
providing an electrical component having a first end and a second end;
inserting the electrical component into the substrate via so that the first end extends at least partially inside the first substrate and the second end extends at least partially inside the second substrate; and
forming an electrically insulating layer between the first substrate and the second substrate.

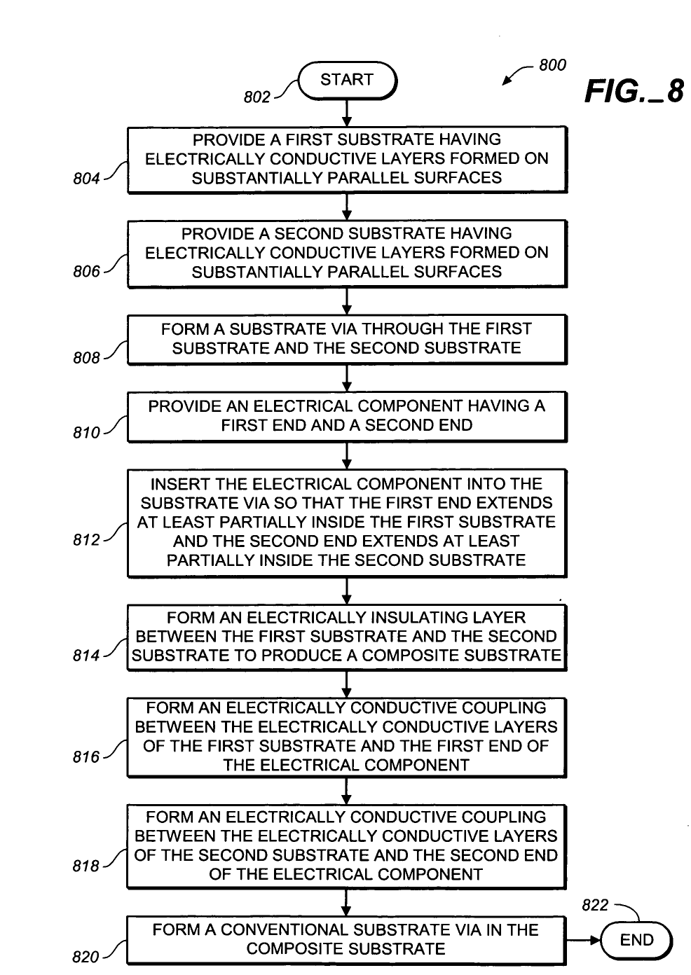

FIG. 8 illustrates a flow chart 800 of a method according to an embodiment of an integrated circuit package substrate with an electrical component embedded in a substrate via.

Step 802 is the entry point of the flow chart 800.

In step 804, a first substrate is provided having electrically conductive layers formed on substantially parallel surfaces of the first substrate.

In step 806, a second substrate is provided having electrically conductive layers formed on substantially parallel surfaces of the second substrate.

In step 808, a substrate via is formed through the first substrate and the second substrate to form an electrical connection between at least two electrically conductive layers of the first substrate and between at least two electrically conductive layers of the second substrate.

In step 810, an electrical component is provided having a first end and a second end. The electrical component may be, for example, a resistor, a capacitor, or other passive electrical component. The electrical component preferably has a diameter that is less than the diameter of the substrate.

In step 812, the electrical component is inserted into the substrate via so that the first end extends at least partially inside the first substrate and the second end extends at least partially inside the second substrate. The ends of the electrical component may be temporarily supported, for example, by a backing plate, until the following step has been performed.

In step 814, an electrically insulating layer is formed between the first substrate and the second substrate to produce a composite substrate. The electrically insulating layer may be formed, for example, by injecting an electrically insulating liquid such as a liquid filler between the first substrate and the second substrate and curing the liquid into a solid. The solidified electrically insulating layer secures the first substrate to the second substrate and secures the electrical component inside the substrate via.

In step 816, an electrically conductive coupling is formed between the electrically conductive layers of the first substrate and the first end of the electrical component. The electrically conductive coupling may be formed, for example, by injecting an electrically conductive liquid such as a conductive epoxy compound into the end of the substrate via on the first substrate and curing the liquid into a solid.

In step 818, an electrically conductive coupling is formed between the electrically conductive layers of the second substrate and the second end of the electrical component. The electrically conductive coupling may be formed, for example, by inverting the composite substrate, injecting an electrically conductive liquid into the end of the substrate via on the second substrate, and curing the liquid into a solid.

In step 820, a conventional substrate via may be optionally formed in the composite substrate according to well-known techniques. The conventional substrate via provides an electrical connection between wire traces formed in the electrically conductive layers of the first substrate to wire traces formed in the electrically conductive layers of the second substrate.

Step 822 is the exit point of the flow chart 800.

Although the flowchart description above is described and shown with reference to specific steps performed in a specific order, these steps may be combined, sub-divided, or reordered without departing from the scope of the claims. Unless specifically indicated, the order and grouping of steps is not a limitation of other embodiments that may lie within the scope of the claims.

The specific embodiments and applications thereof described above are for illustrative purposes only and do not preclude modifications and variations that may be made within the scope of the following claims.

What is claimed is:

1. An integrated circuit package comprising:
a first substrate having electrically conductive layers formed on substantially parallel surfaces of the first substrate;
a second substrate having electrically conductive layers formed on substantially parallel surfaces of the second substrate;
a substrate via formed through the first substrate and the second substrate to form an electrical connection between at least two electrically conductive layers of the first substrate and between at least two electrically conductive layers of the second substrate;
an electrical component having a first end and a second end inserted into the substrate via so that the first end extends at least partially inside the first substrate and the second end extends at least partially inside the second substrate; and
an electrically insulating layer formed between the first substrate and the second substrate.

2. The integrated circuit package of claim 1 further comprising an electrically conductive coupling formed between the at least two electrically conductive layers of the first substrate and the first end of the electrical component.

3. The integrated circuit package of claim 2 wherein the electrically conductive coupling is an electrically conductive liquid that is cured to form a solid.

4. The integrated circuit package of claim 1 further comprising an electrically conductive coupling formed between the at least two electrically conductive layers of the second substrate and the second end of the electrical component.

5. The integrated circuit package of claim 4 wherein the electrically conductive coupling is an electrically conductive liquid that is cured to form a solid.

6. The integrated circuit package of claim 1 wherein the second substrate is electrically insulated from the first substrate by an electrically non-conductive liquid injected between the first substrate and the second substrate and cured to form a solid.

7. The integrated circuit package of claim 6 further comprising a second substrate via formed through the first substrate and the second substrate to provide an electrical connection between a portion of an electrically conductive layer in the first substrate and a portion of an electrically conductive layer in the second substrate.

8. The integrated circuit package of claim 1 wherein the electrical component is a capacitor.

9. The integrated circuit package of claim 1 wherein the electrical component is a resistor.

10. The integrated circuit package of claim 1 wherein the electrical component is a passive electrical component.

11. A method comprising steps of:
(a) providing a first substrate having electrically conductive layers formed on substantially parallel surfaces of the first substrate;
(b) providing a second substrate having electrically conductive layers formed on substantially parallel surfaces of the second substrate;
(c) forming a substrate via through the first substrate and the second substrate to form an electrical connection between at least two electrically conductive layers of the first substrate and between at least two electrically conductive layers of the second substrate;
(d) providing an electrical component having a first end and a second end;
(e) inserting the electrical component into the substrate via so that the first end extends at least partially inside the first substrate and the second end extends at least partially inside the second substrate; and
(f) forming an electrically insulating layer between the first substrate and the second substrate.

12. The method of claim 11 further comprising a step of forming a second substrate via through the first substrate, the electrically insulating layer, and the second substrate to provide an electrical connection between a portion of an electrically conductive layer in the first substrate and a portion of an electrically conductive layer in the second substrate.

13. The method of claim 11 further comprising a step of forming an electrically conductive coupling between the at least two electrically conductive layers of the first substrate and the first end of the electrical component.

14. The method of claim 13 wherein the step of forming an electrically conductive coupling comprises curing an electrically conductive liquid to form a solid.

15. The method of claim 11 further comprising a step of forming an electrically conductive coupling between the at least two electrically conductive layers of the second substrate and the second end of the electrical component.

16. The method of claim 15 wherein the step of forming an electrically conductive coupling comprises curing an electrically conductive liquid to form a solid.

17. The method of claim 11 wherein step (f) comprises injecting an electrically non-conductive liquid between the first substrate and the second substrate and curing the electrically non-conductive liquid to form a solid.

18. The method of claim 11 wherein step (d) comprises providing a capacitor.

19. The method of claim 11 wherein step (d) comprises providing a resistor.

20. The method of claim 11 wherein step (d) comprises providing a passive electrical component.
